(19) United States
(12) Patent Application Publication
(10) Pub. No.: US 2025/0079247 A1
(43) Pub. Date: Mar. 6, 2025

(54) MOLD COMPOUND TRENCHES TO FACILITATE PACKAGE SINGULATION

(71) Applicant: TEXAS INSTRUMENTS INCORPORATED, Dallas, TX (US)

(72) Inventors: Makoto SHIBUYA, Tokyo (JP); Shoichi IRIGUCHI, Beppu-Shi Oita-Ken (JP); Hideaki MATSUNAGA, Beppu-Shi Oita-Ken (JP)

(21) Appl. No.: 18/459,119

(22) Filed: Aug. 31, 2023

(51) Int. Cl. H01L 23/31; H01L 21/56; H01L 23/00; H01L 23/495

(52) U.S. Cl. CPC H01L 23/3107; H01L 21/561; H01L 23/49503; H01L 24/97; H01L 24/48; H01L 2224/48245; H01L 2224/97

(57) ABSTRACT

In examples, a semiconductor package comprises a semiconductor die having a device side in which circuitry is formed, and a conductive terminal coupled to the device side of the semiconductor die. The package also comprises a mold compound covering the semiconductor die and at least part of the conductive terminal, where the conductive terminal is exposed to an exterior of the mold compound. The mold compound has top and bottom surfaces and a lateral side extending between the top and bottom surfaces. The lateral side includes a first surface contacting the top surface and extending vertically from the top surface toward the bottom surface. The lateral side also includes a second surface contacting the first surface and extending horizontally away from the semiconductor die. The lateral side also includes a third surface contacting the second surface and extending from the second surface to contact the bottom surface. The third surface has physical marks resulting from a singulation process. The first and second surfaces lack physical marks resulting from the singulation process.

### BACKGROUND

Semiconductor chips are often housed inside semiconductor packages that protect the chips from deleterious environmental influences, such as heat, moisture, and debris. A packaged chip communicates with electronic devices outside the package via conductive members, such as leads, that are exposed to surfaces of the package. Within the package, the chip may be electrically coupled to the conductive members using any suitable technique. One such technique is the flip-chip technique, in which the semiconductor chip (also called a “die”) is flipped so the device side of the chip (in which circuitry is formed) is facing downward. The device side is coupled to the conductive members using, e.g., solder bumps. Another technique is the wirebonding technique, in which the device side of the semiconductor chip is oriented upward and is coupled to the conductive members using bond wires. A mold compound covers the various components of each chip, such as the die, wirebonds, and portions of the leads.

### SUMMARY

In examples, a semiconductor package comprises a semiconductor die having a device side in which circuitry is formed, and a conductive terminal coupled to the device side of the semiconductor die. The package also comprises a mold compound covering the semiconductor die and at least part of the conductive terminal, where the conductive terminal is exposed to an exterior of the mold compound. The mold compound has top and bottom surfaces and a lateral side extending between the top and bottom surfaces. The lateral side includes a first surface contacting the top surface and extending vertically from the top surface toward the bottom surface. The lateral side also includes a second surface contacting the first surface and extending horizontally away from the semiconductor die. The lateral side also includes a third surface contacting the second surface and extending from the second surface to contact the bottom surface. The third surface has physical marks resulting from a singulation process. The first and second surfaces lack physical marks resulting from the singulation process.

In examples, a method for manufacturing a semiconductor package comprises: coupling multiple semiconductor dies to multiple die pads of a high-density lead frame; coupling each of the multiple semiconductor dies to conductive terminals of the high-density lead frame; positioning the high-density lead frame and the semiconductor dies in a mold chase, the mold chase having protrusions positioned between consecutive ones of the multiple die pads; causing mold compound to cover the semiconductor dies in the mold chase and flow underneath the protrusions in the mold chase, wherein portions of the mold compound covering the semiconductor dies are thicker than portions of the mold compound between the semiconductor dies; removing the high-density lead frame from the mold chase; trimming the high-density lead frame; and singulating the mold compound-covered multiple semiconductor dies from each other to produce semiconductor packages, wherein the singulation is performed by using a tool to cut through the portions of the mold compound between the semiconductor dies.

### BRIEF DESCRIPTION OF THE DRAWINGS

FIG. 1 is a flow diagram of a process for manufacturing semiconductor packages using mold compound trenches to facilitate package singulation, in accordance with various examples.

FIG. 2A is a perspective view of a lead frame having semiconductor dies coupled thereto, in accordance with various examples.

FIG. 2B is a top-down view of a lead frame having semiconductor dies coupled thereto, in accordance with various examples.

FIG. 2C is a profile view of a lead frame having semiconductor dies coupled thereto, in accordance with various examples.

FIG. 2D is a profile view of a lead frame having semiconductor dies coupled thereto, in accordance with various examples.

FIG. 3A is a mold chase member configured to form mold compound trenches that facilitate package singulation, in accordance with various examples.

FIG. 3B is a top-down view of a mold chase member configured to form mold compound trenches that facilitate package singulation, in accordance with various examples.

FIG. 3C is a profile view of a mold chase member configured to form mold compound trenches that facilitate package singulation, in accordance with various examples.

FIG. 3D is a profile view of a mold chase member configured to form mold compound trenches that facilitate package singulation, in accordance with various examples.

FIG. 3E is a bottom-up view of a mold chase member configured to form mold compound trenches that facilitate package singulation, in accordance with various examples.

FIG. 4A is a perspective view of a mold chase member configured to form mold compound trenches that facilitate package singulation being lowered onto a lead frame having semiconductor dies coupled thereto, in accordance with various examples.

FIG. 4B is a perspective view of a mold chase member configured to form mold compound trenches that facilitate package singulation being lowered onto a lead frame having semiconductor dies coupled thereto, in accordance with various examples.

FIG. 4C is a perspective view of a mold chase member being used to form mold compound trenches that facilitate package singulation on a lead frame having semiconductor dies coupled thereto, in accordance with various examples.

FIG. 4D is a perspective view of a mold chase member having been used to form mold compound trenches that facilitate package singulation on a lead frame having semiconductor dies coupled thereto, in accordance with various examples.

FIG. 5A is a perspective view of a lead frame strip covered by a mold compound having trenches that facilitate package singulation, in accordance with various examples.

FIG. 5B is a top-down view of a lead frame strip covered by a mold compound having trenches that facilitate package singulation, in accordance with various examples.

FIG. 5C is a profile view of a lead frame strip covered by a mold compound having trenches that facilitate package singulation, in accordance with various examples.

FIG. 5D is a profile view of a lead frame strip covered by a mold compound having trenches that facilitate package singulation, in accordance with various examples.

FIG. 6A is a perspective view of a package having been singulated from a mold compound bar using mold compound trenches that facilitate package singulation, in accordance with various examples.

FIG. 6B is a top-down view of a package having been singulated from a mold compound bar using mold compound trenches that facilitate package singulation, in accordance with various examples.

FIG. 6C is a profile view of a package having been singulated from a mold compound bar using mold compound trenches that facilitate package singulation, in accordance with various examples.

FIG. 6D is a profile view of a package having been singulated from a mold compound bar using mold compound trenches that facilitate package singulation, in accordance with various examples.

FIG. 6E is a bottom-up view of a package having been singulated from a mold compound bar using mold compound trenches that facilitate package singulation, in accordance with various examples.

FIG. 7A is a perspective view of a package having been singulated from a mold compound bar using mold compound trenches that facilitate package singulation, in accordance with various examples.

FIG. 7B is a top-down view of a package having been singulated from a mold compound bar using mold compound trenches that facilitate package singulation, in accordance with various examples.

FIG. 7C is a profile view of a package having been singulated from a mold compound bar using mold compound trenches that facilitate package singulation, in accordance with various examples.

FIG. 7D is a profile view of a package having been singulated from a mold compound bar using mold compound trenches that facilitate package singulation, in accordance with various examples.

FIG. 7E is a bottom-up view of a package having been singulated from a mold compound bar using mold compound trenches that facilitate package singulation, in accordance with various examples.

FIG. 8A is an example of a mold compound surface bearing at least some physical evidence of a mechanical sawing process.

FIG. 8B is an example of a mold compound surface bearing at least some physical evidence of a laser sawing process.

### DETAILED DESCRIPTION

During the semiconductor package manufacturing process, different semiconductor dies may be coupled to different die pads on a lead frame strip, each die coupled to a separate die pad. The die may be coupled to the leads of the lead frame strip, such as by wirebonding or soldering. The entire lead frame strip may then be positioned inside a mold chase, and mold compound may be injected into the mold chase, thereby covering the lead frame strip, including the different semiconductor dies and their respective die pads, with the mold compound. The resulting structure is a mold compound “bar” that contains within it a lead frame strip having multiple die pads and multiple semiconductor dies, along with their respective wirebonds, solder bumps, and so on. The bar is then singulated to produce individual semiconductor packages. The bar singulation may be performed using laser or mechanical saws, for example.

A major challenge in the package manufacturing process is increasing throughput. Mechanical saws are tedious and slow in singulating mold compound bars to produce individual packages. Laser saws are significantly more efficient than mechanical saws, but the mold compound bars are frequently too thick to accommodate laser saws. Thus, manufacturing throughput remains suboptimal.

In certain contexts, the aforementioned challenges are exacerbated. For example, some lead frame designs considered “high-density” lead frames, meaning that a given length or area of lead frame can produce a significantly greater number of packages than can be produced by other, non-high-density lead frame designs. As used herein, a high-density lead frame is a lead frame in which die pads occupy more than 50% of the total area of the lead frame. However, the potential of such high-density lead frames is not fully realized because of the limits in manufacturing throughput described above.

This disclosure describes various examples of a semiconductor package manufacturing process that mitigates the technical challenges described above. Specifically, the process described herein entails the use of a mold chase that is specifically structured to form mold compound trenches in between each successive pair of dies (or die pads) in a lead frame strip. When the lead frame strip is removed from the mold chase, the resulting mold compound bar does not have a uniform thickness, but rather includes a series of trenches along its length. These trenches are areas of mold compound that are sufficiently thin for a laser saw to effectively and efficient cut. Thus, by using such mold chases to form mold compound trenches, the laser saw becomes usable to singulate the mold compound bars to produce individual packages, which significantly increases manufacturing throughput. Even if a mechanical saw is used in lieu of a laser saw, cutting through a thinner mold compound results in diminished wear and tear on the mechanical saw and improved dicing efficiency. The process described herein, as well as the semiconductor packages resulting from the process, thus represent a specific technical solution to a specific technical challenge. These increases in manufacturing throughput are particularly effective in the context of high-density lead frames, as the more efficient processes described herein can help fully realize the high throughput potential of such high-density lead frames. The examples described herein may also present various other benefits, such as a reduction in mold compound usage. Examples of the process and example packages resulting from the process are now described with reference to the drawings.

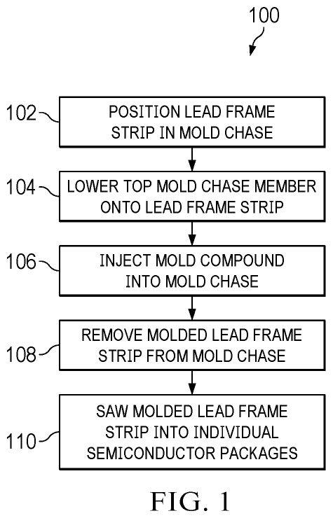

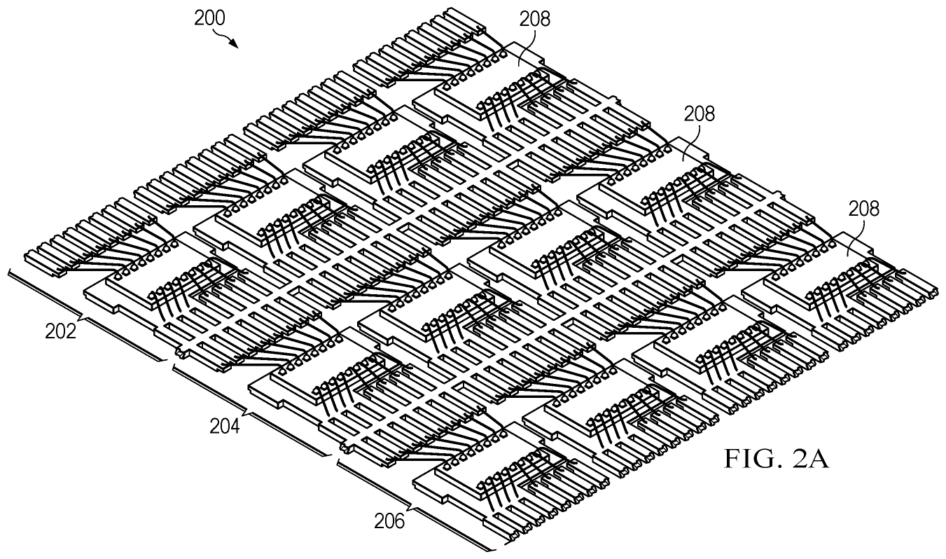

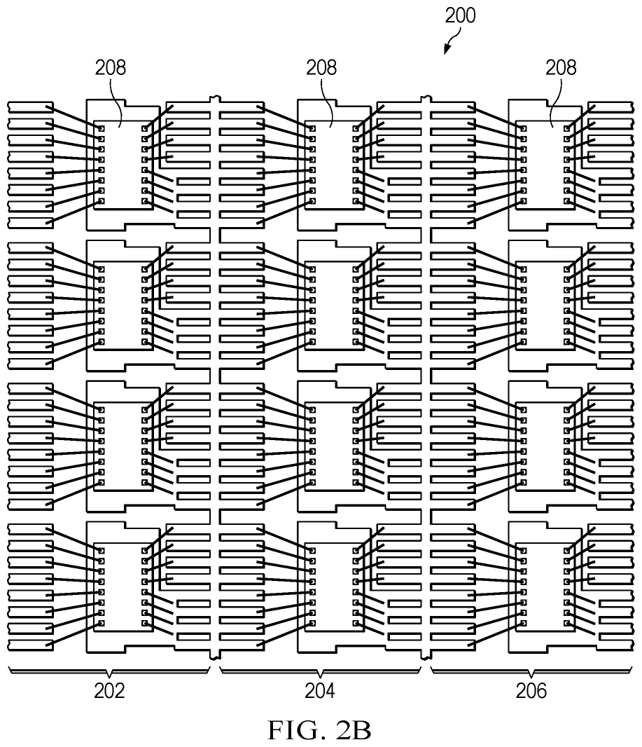

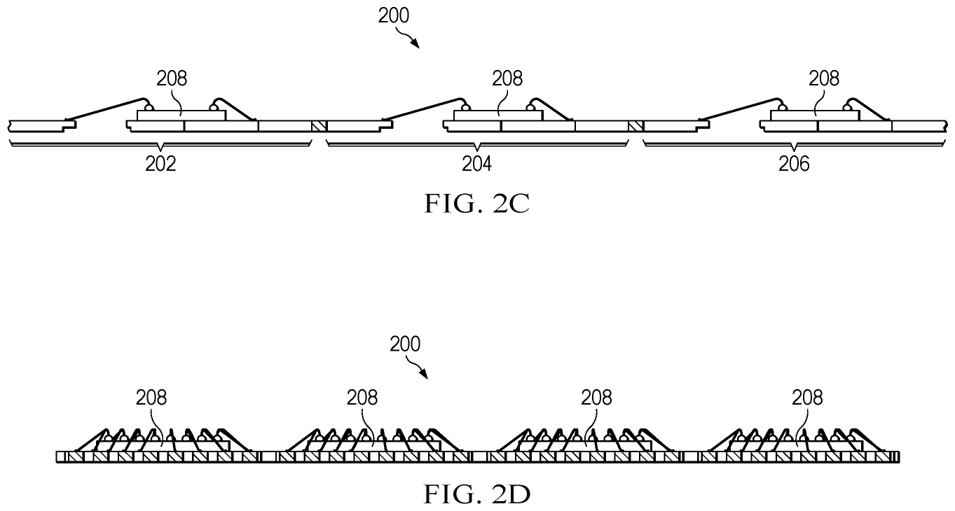

FIG. 1 is a flow diagram of a process 100 for manufacturing semiconductor packages using mold compound trenches to facilitate package singulation, in accordance with various examples. The process 100 includes positioning a lead frame strip in a mold chase (102). The lead frame strip may include one or more rows and/or one or more columns of die pads connected to each other by leads, tie bars, dam bars, etc. The lead frame strip may comprise copper or any other suitable metal or alloy. Semiconductor dies may be positioned on the die pads, for example using die attach layers. The semiconductor dies may be coupled to the leads by way of wirebonds, solder bumps, etc. FIG. 2A is a perspective view of an example lead frame strip 200 having multiple columns 202, 204, and 206. In examples, tens, dozens, hundreds, or thousands of columns may be included in the lead frame strip 200. Semiconductor dies 208 are coupled to die pads of the lead frame strip 200. Additional components, such as wirebonds, may be included as well. FIG. 2B is a top-down view of the lead frame strip 200, in accordance with various examples. FIG. 2C is a profile view of the lead frame strip 200, in accordance with various examples. FIG. 2D is a profile view of the lead frame strip 200, in accordance with various examples.

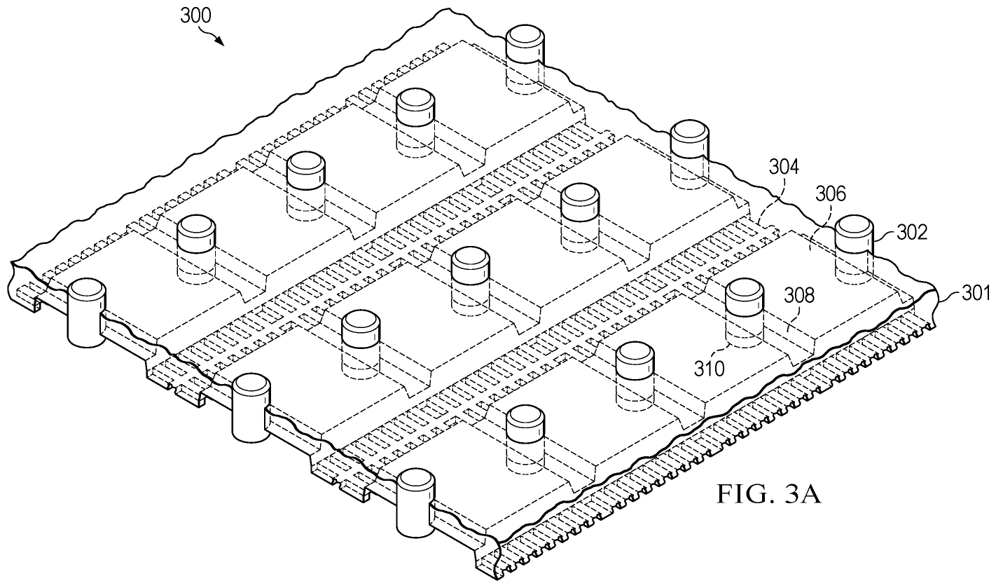

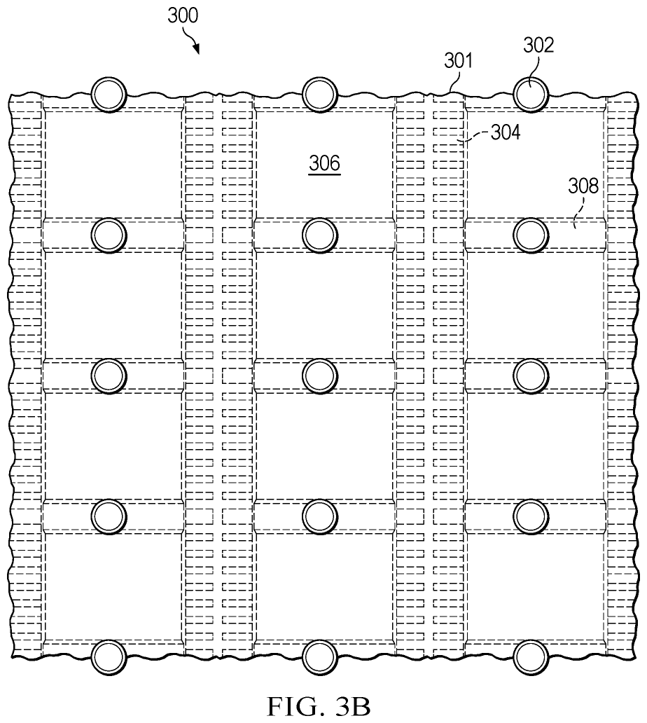

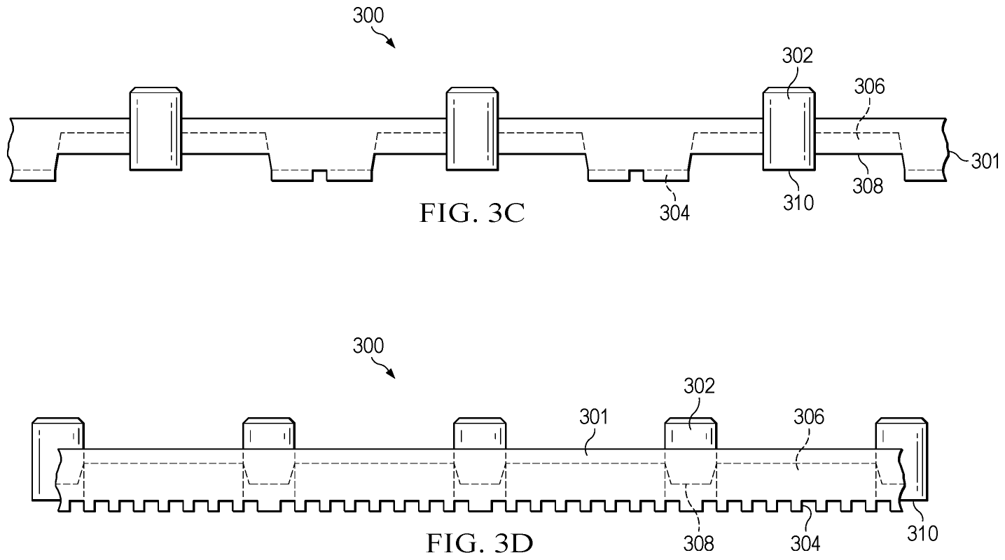

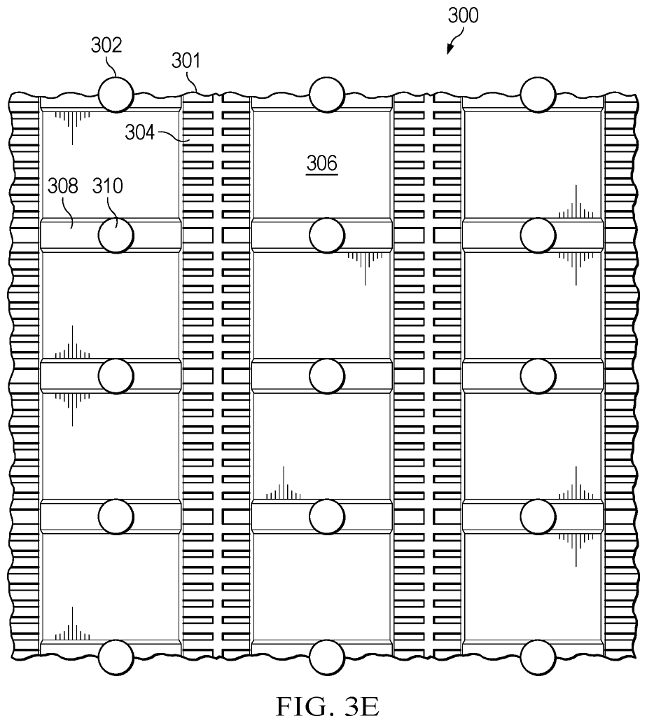

FIG. 3A is a mold chase member 300 configured to form mold compound trenches that facilitate package singulation, in accordance with various examples. The mold chase member 300 includes a body 301 and multiple grip members 302 extending from above a top surface of the body 301 and through the body 301. The grip members are useful for a manufacturing machine (e.g., a robotic arm) to grasp the mold chase member 300. The mold chase member 300 includes lead cavities 304 so that when the mold chase member 300 is lowered onto the lead frame strip 200, the lead cavities 304 mate with the leads on the lead frame strip 200 and providing proper alignment between the lead frame strip 200 and the mold chase member 300. The mold chase member 300 also includes die cavities 306 so that when the mold chase member 300 is lowered onto the lead frame strip 200, the die cavities 306 mate with the semiconductor dies 208 on the lead frame strip 200 and providing proper alignment between the lead frame strip 200 and the mold chase member 300. Without the lead cavities 304 and the die cavities 306, the mold chase member 300 cannot be fully lowered onto the lead frame strip 200, and as a consequence, the mold compound cannot be injected into the mold chase. The presence of the lead cavities 304 and die cavities 306 provides space in which the leads of the lead frame strip 200 and the dies 208 can be housed, thus facilitating proper alignment between the mold chase member 300 and the lead frame strip 200 and facilitating proper mold compound injection.

The example mold chase member 300 may include a trench protrusion 308. The trench protrusion is useful to form the mold compound trenches described herein. As explained, the mold compound underlying the trenches is thinner than other portions of the mold compound bar that is formed after mold compound injection over a lead frame strip, and thus sawing through the mold compound beneath the trenches is easier than sawing through thicker portions of the mold compound bar. The trench protrusion 308, and thus the resulting mold compound trench, may be of any suitable shape. In some examples, two or more lateral sides of the trench protrusion 308 may be angled to produce a wedge-shaped mold compound trench, but the scope of this disclosure is not limited as such. The trench protrusion 308 should be sized to produce a mold compound thickness underneath the trench that is between 500 microns and 1000 microns, with a trench protrusion that produces a mold compound thickness below this range being disadvantageous because it can impede proper mold compound flow (e.g., resulting in voiding challenges), and with a trench protrusion that produces a mold compound thickness above this range being disadvantageous because the improved manufacturing throughput and/or increased mechanical saw longevity is not realized. In examples, the grip members 302 extend through the trench protrusions 308 and below a bottom surface of the trench protrusions 308, although the scope of this disclosure is not limited as such. Grip members 302, also known as pillars, prevent mold flashing during the mold compound application process by adding downward force on lead frame die pads. FIG. 3B is a top-down view of the mold chase member 300, in accordance with various examples. FIG. 3C is a profile view of the mold chase member 300, in accordance with various examples. FIG. 3D is a profile view of the mold chase member 300, in accordance with various examples. FIG. 3E is a bottom-up view of the mold chase member 300, in accordance with various examples.

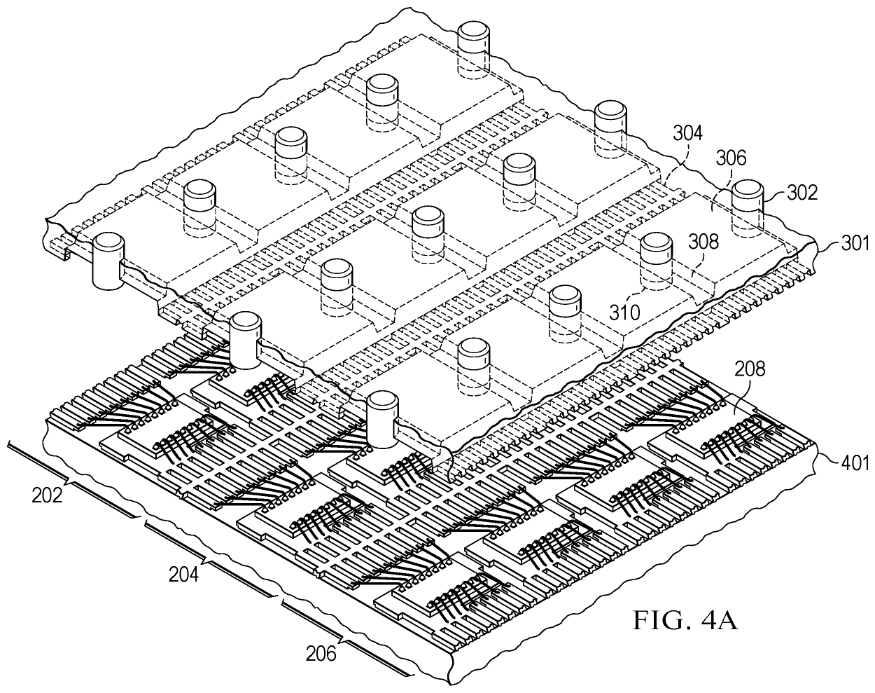

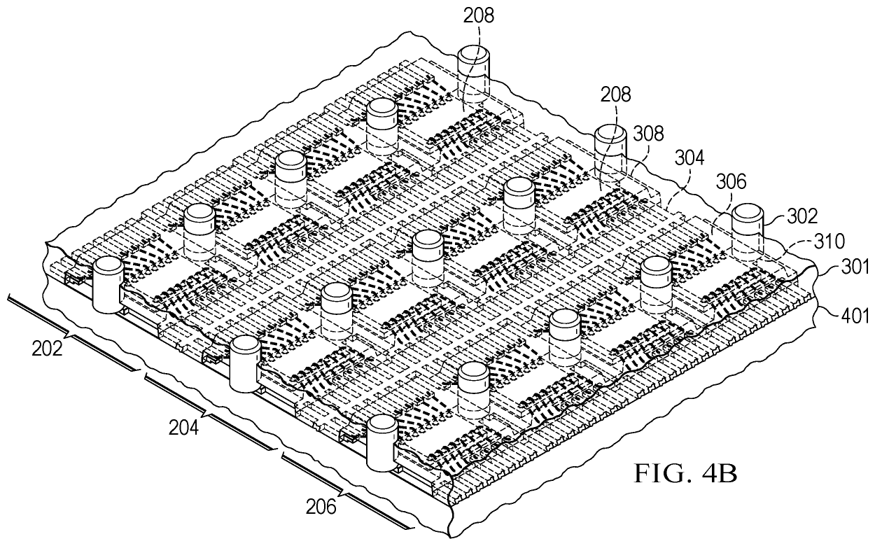

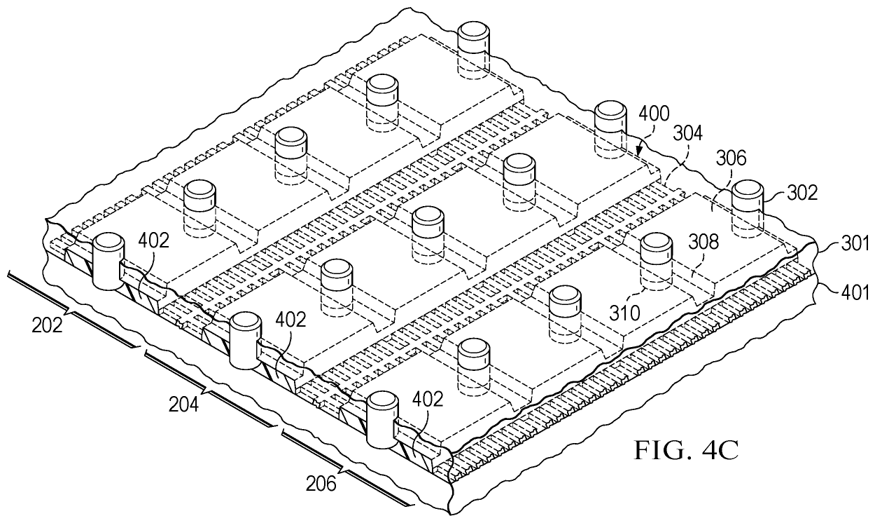

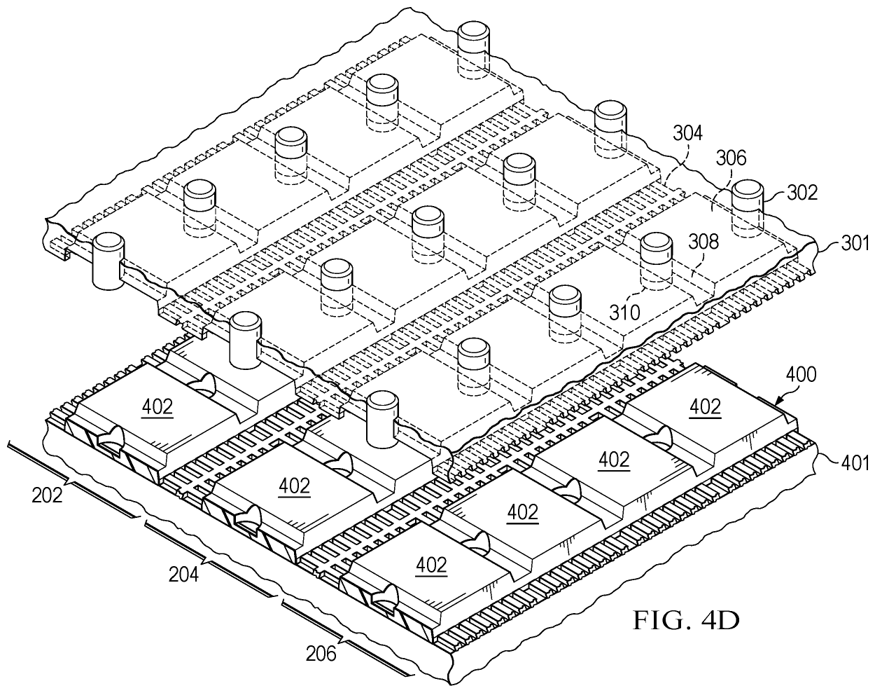

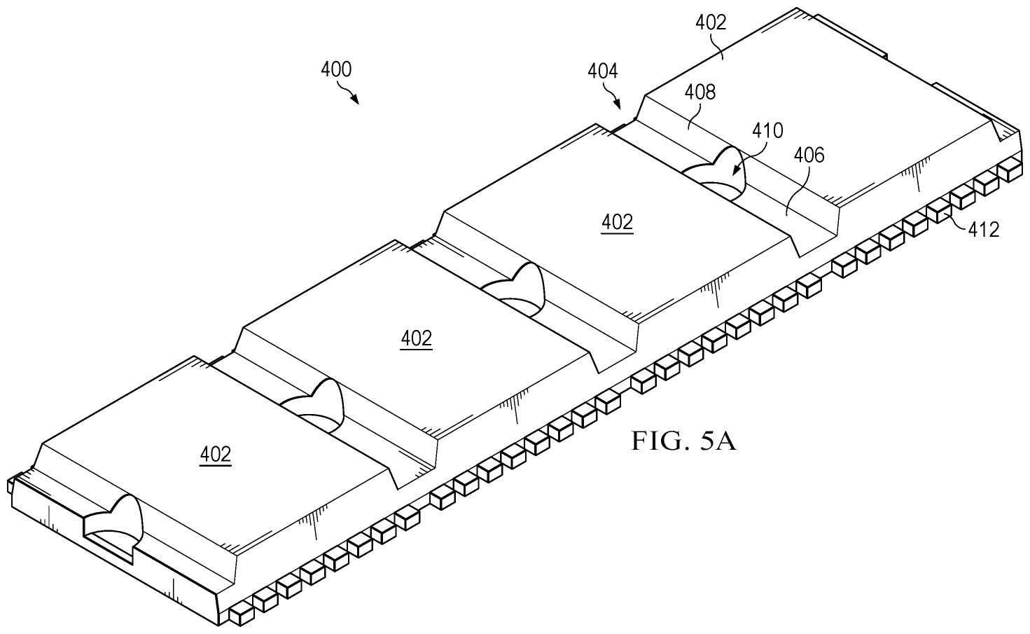

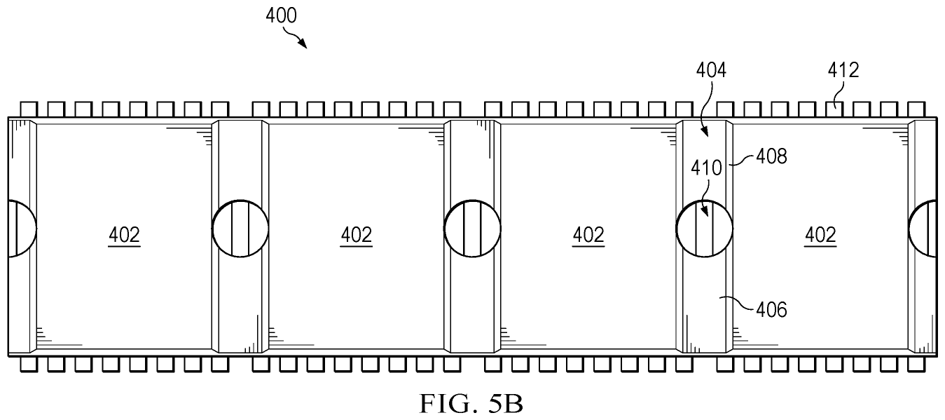

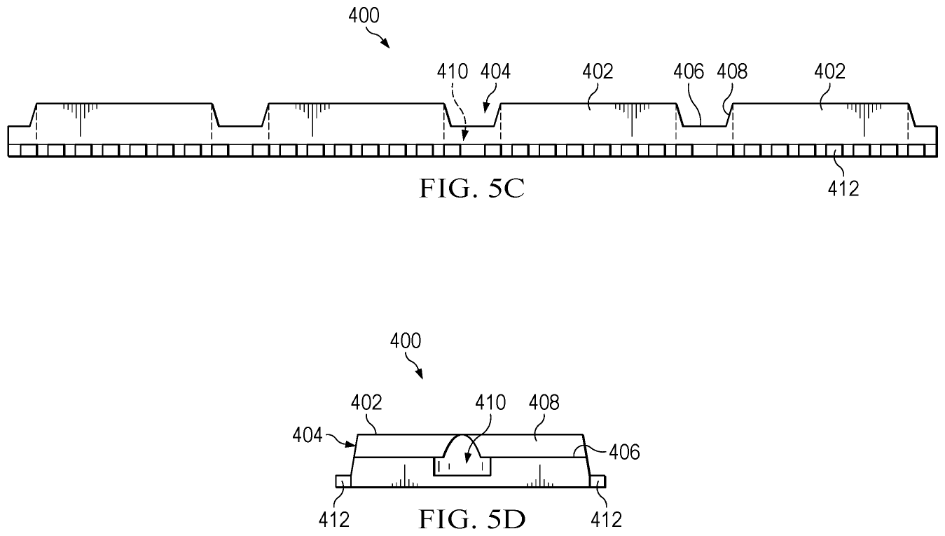

FIG. 4A is a perspective view of the lead frame strip 200 positioned in a mold chase, and more specifically, on a bottom mold chase member 401. The mold chase member 300 is positioned above the lead frame strip 200. The process 100 comprises lowering the mold chase member onto the lead frame strip 200 to mate with the lead frame strip 200 (104), as shown in FIG. 4B, and the process 100 also comprises injecting mold compound into the mold chase to cover the lead frame strip 200 and all components coupled thereto with mold compound (106), as shown in FIG. 4C. The injected mold compound may flow throughout the mold chase, for example, by covering the semiconductor dies 208, flowing under the protrusions 308, and flowing around the segments 310 of grip members 302 that extend below the protrusions 308. The mold chase is then opened, as shown in FIG. 4D, and the molded lead frame strip, also known as the mold compound bar, is removed from the mold chase (108). FIG. 5A is a perspective view of the resulting mold compound bar 400. The mold compound bar 400 is the lead frame strip 200 covered by a mold compound. Mold compound portions 402 cover respective semiconductor dies 208. Each successive pair of mold compound portions 402 are separated by mold compound trenches 404. The trenches 404 are formed by trench protrusions 308, described above. Each trench 404 includes a surface 406, a surface 408, and a cavity 410 that extends through the surfaces 406 and 408. The thickness of the mold compound below the trench 404 (i.e., below surface 406) is within the range described above and is significantly thinner than the mold compound portions 402. In some examples, the surfaces 408 are vertical and normal to the top surface of the mold compound portion 402 and the surface 406. In some examples, the surfaces 408 are vertical and are slanted, as shown in FIG. 5A. In some examples, the surface 406 does not exist, meaning the surfaces 408 of a particular trench 404 converge with each other. Leads 412 extend from the mold compound bar 400 as shown. FIG. 5B is a top-down view of the mold compound bar 400, in accordance with various examples. FIG. 5C is a profile view of the mold compound bar 400, in accordance with various examples. FIG. 5D is a profile view of the mold compound bar 400, in accordance with various examples.

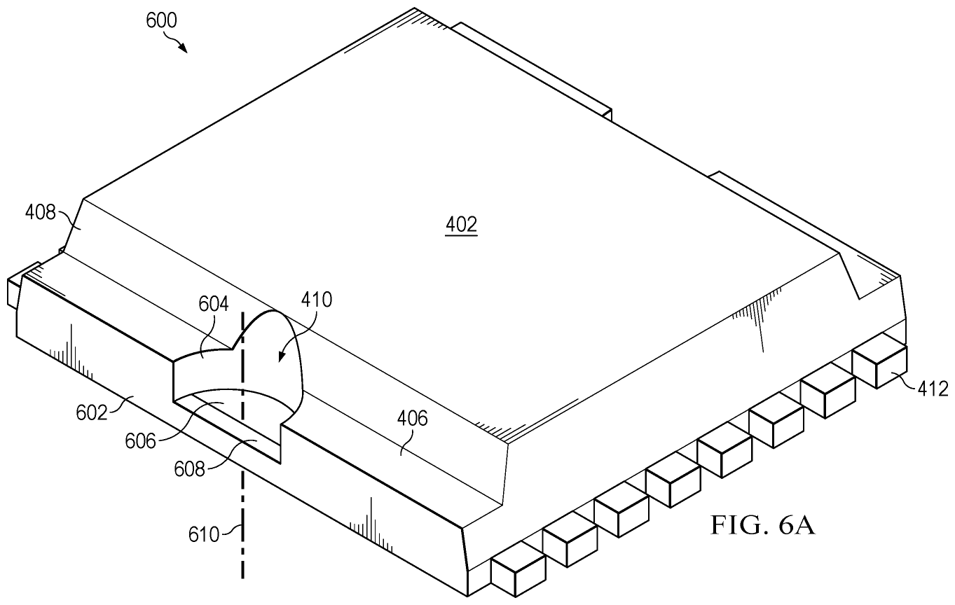

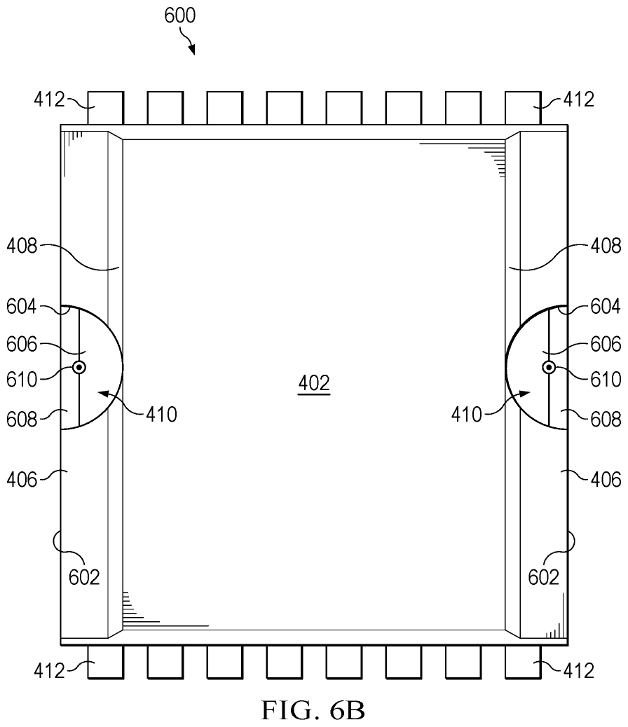

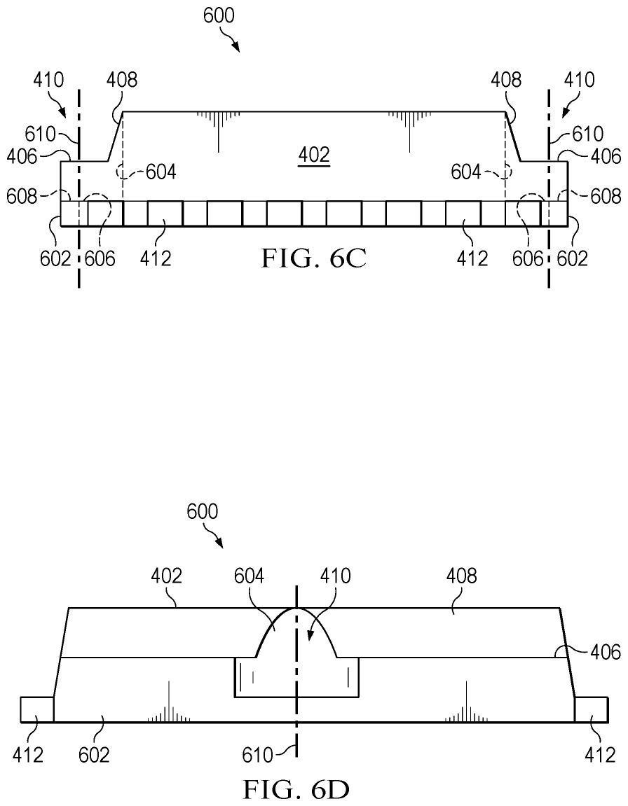

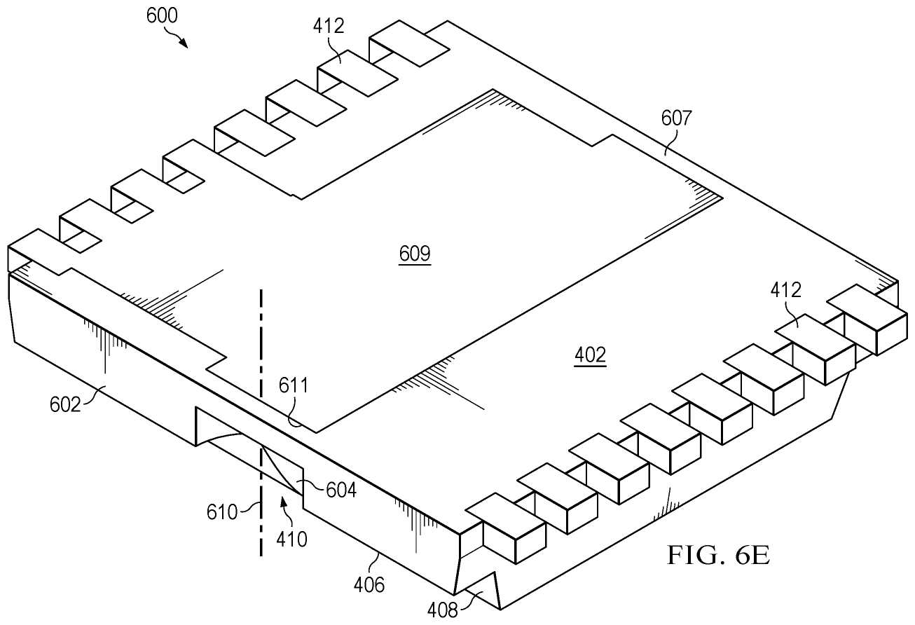

Although not expressly shown in FIG. 1, a trimming process may be performed to trim leads, dam bars, tie bars, etc. The process 100 subsequently comprises sawing the molded lead frame strip (i.e., mold compound bar 400) into individual semiconductor packages (110). FIG. 6A is a perspective view of a package 600 having been singulated from a mold compound bar 400 using mold compound trenches that facilitate package singulation, in accordance with various examples. The example package 600 includes the mold compound portion 402 to contain a semiconductor die 208. The package 600 includes surfaces 408 on opposing sides of the mold compound portion 402. The package 600 includes surfaces 406 on opposing sides of the mold compound portion 402. The package 600 includes surfaces 602 on opposing sides of the mold compound portion 402. The surfaces 408 contact the top surface of the package 600; the surfaces 406 contact the respective surfaces 408; the surfaces 602 contact the respective surfaces 406; and the surfaces 406 contact the bottom surface of the package 600. The cavity 410 extends from the top surface of the mold compound portion 402 and through the thickness of the package 600, and is coincident with the surfaces 408, 406, and 602. The cavity 410 includes a curved wall 604 and a bottom surface including a metal portion 606 and a mold compound portion 608. Leads 412 extend from opposing ends of the package 600, as shown.

In examples, the surface 408 is not normal to the surface 406, and in other examples, the surface 408 is normal to the surface 406. The height of the surface 602 represents the thickness of mold compound through which a laser or mechanical saw must cut, and the critical range for this height (which is less than the height of the package 600), along with the consequences for exceeding this range and falling below this range, are provided above. The bottom surface (i.e., floor) of the cavity 410 is coincident with a horizontal plane that is above the bottom surface of the package 600 and below the horizontal plane in which the surface 406 lies.

The length of the cavity 410 along the lengths of the surfaces 602, 406, 408, and the top surface of the mold compound portion 402 is variable. The greater the length of this cavity 410, the less mold compound that must be cut during singulation of the mold compound bar 400. This, in turn, results in less wear and tear on mechanical saws, and it results in greater throughput for both mechanical and laser saws. However, the length of this cavity 410 is less than 1000 microns, with a length above this range being disadvantageous because it can reveal bond wires that would otherwise be covered by the mold compound.

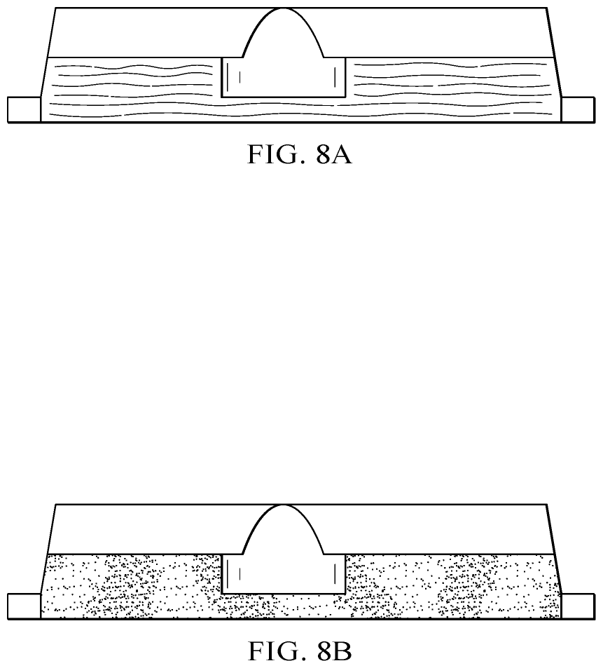

The surface 602 bears physical marks evidencing a singulation process, such as a laser or mechanical sawing process. These physical marks result when a laser or mechanical saw is applied to the mold compound bar 400 to singulate the mold compound bar 400. When a semiconductor package mold compound is singulated by a mechanical saw, the process can leave physical evidence on the sidewall of the mold compound. The physical evidence of mechanical saw singulation can include saw marks. These marks are typically straight lines or grooves caused by the motion of the mechanical saw blade as it cuts through the mold compound. The evidence can also include fracture lines or cracks on the sidewall of the mold compound. These are formed due to the stress applied during the sawing process, as the mechanical saw cuts through the material. The evidence can also include chipping or delamination of the mold compound on the sidewall. This can happen when the cutting action is not smooth or if the mold compound has certain properties that make it more prone to chipping. The evidence can also include a rough or uneven surface, which is a result of the material being removed by the saw blade, which can create an irregular surface. The evidence can further include residue or particles of the mold compound left on the sidewall or around the edges. These particles can be a byproduct of the cutting process. The evidence can also include discoloration due to the heat generated during the sawing process. This discoloration can be seen as a darkening or change in the appearance of the material. FIG. 8A is an example of a mold compound surface bearing at least some physical evidence of a mechanical sawing process.

When a semiconductor package mold compound is singulated by a laser saw, the process can leave physical evidence on the sidewall of the mold compound. The evidence can include a narrow and well-defined laser kerf, which is a region where the material has been removed to separate the individual semiconductor packages. The evidence can include a Heat-Affected Zone (HAZ) around the edges of the cut. This area may appear slightly different in color or texture due to the localized heat generated by the laser. In some cases, the laser cutting process can result in slight tapering or sloping of the sidewalls. This effect is more common when cutting through thicker mold compound layers. The evidence can include micro-cracks or fracture lines on the sidewall. These are not as pronounced as those found in mechanical sawing. The evidence can include resolidified material, which occurs due to the localized melting and cooling caused by the laser. The evidence can include a minimal degree of charring caused by the laser. FIG. 8B is an example of a mold compound surface bearing at least some physical evidence of a laser sawing process.

FIG. 6B is a top-down view of the package 600, in accordance with various examples. FIG. 6C is a profile view of the package 600, in accordance with various examples. FIG. 6D is a profile view of the package 600, in accordance with various examples.

FIG. 6E is a bottom-up view of the package 600, in accordance with various examples. As shown, a bottom surface 607 of the package 600 includes a die pad 609. The die pad 609 is exposed to an exterior of the package 600 through the bottom surface 607. In examples, the die pad 609 couples to one or more of the leads 412, although the scope of disclosure is not limited as such. An edge 611 of the die pad 609 is within 0.5 mm from a closest edge of the bottom surface 607, such as the edge that the bottom surface 607 shares with the surface 602. The die pad 609 may have multiple such edges 611. Each such edge 611 is vertically aligned with a corresponding cavity 410, meaning that a vertical axis 610 extends through the edge 611 and its respective cavity 410, as shown. As a result, board level reliability (BLR) stress on the edges 611 is reduced, mitigating the risk of mechanical instability, such as solder cracks.

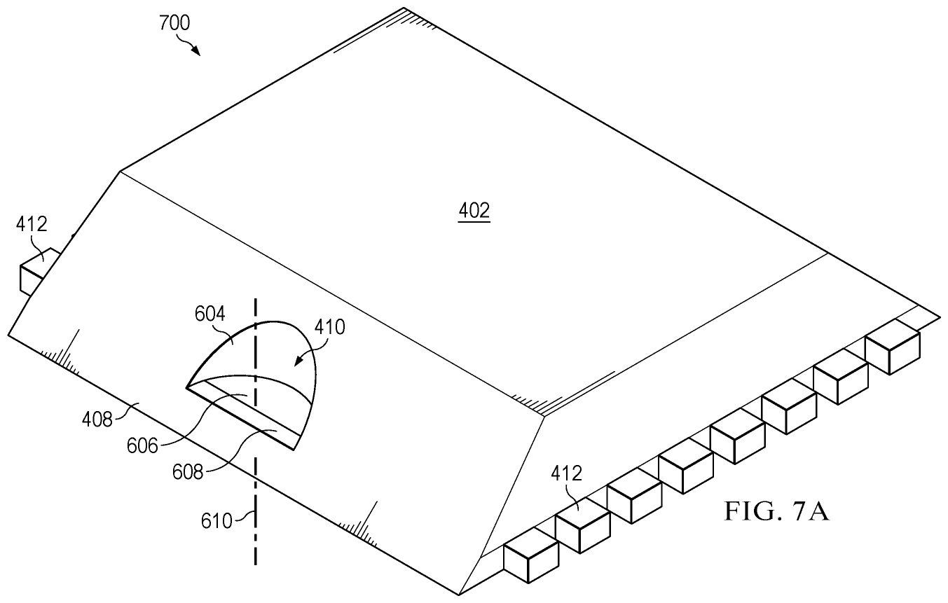

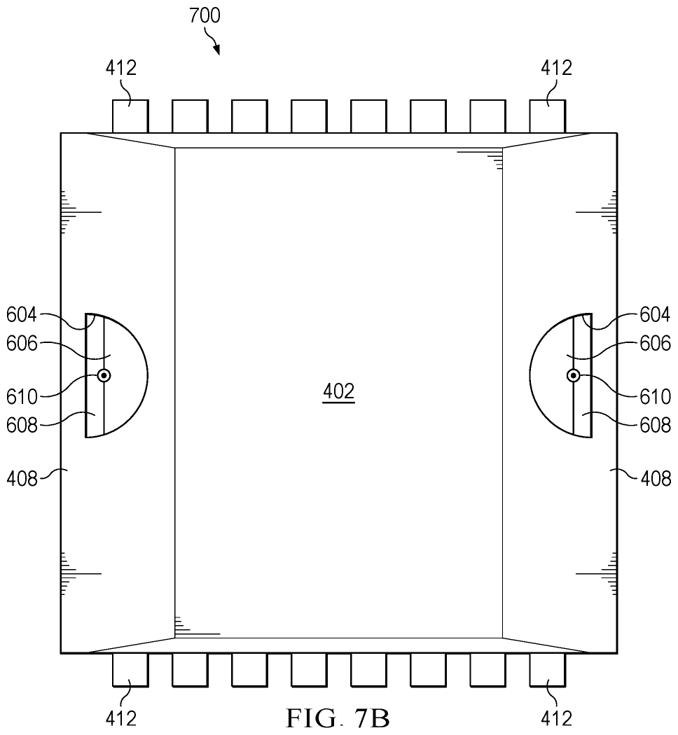

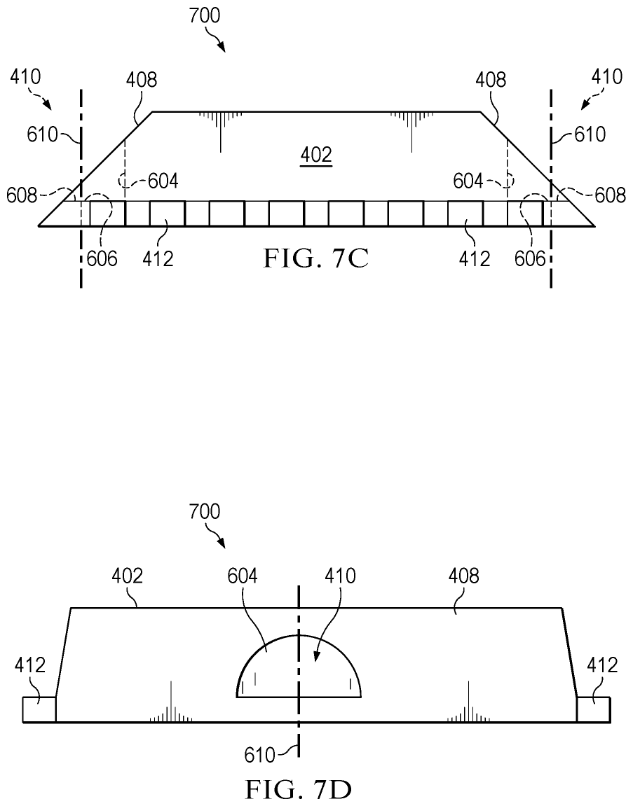

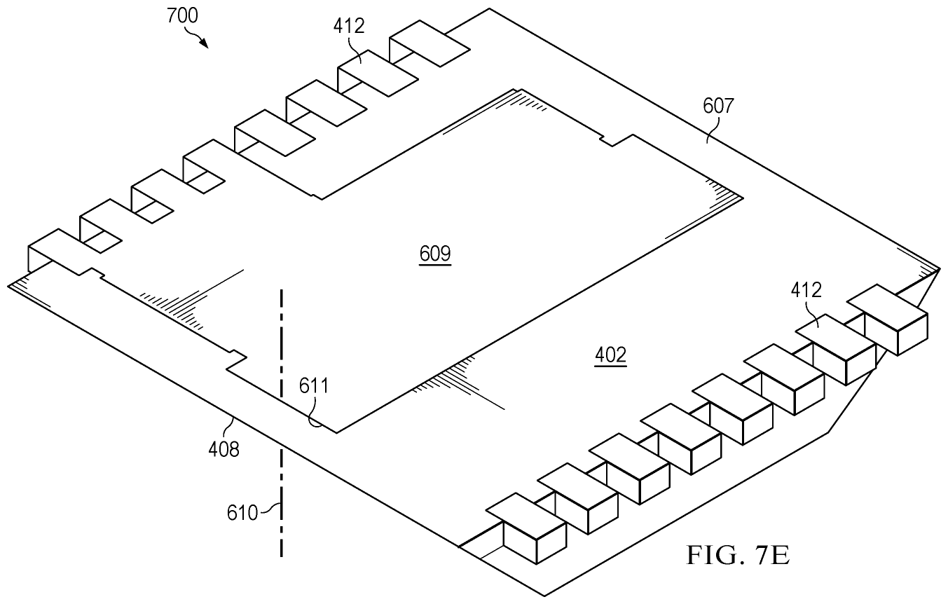

In some examples, the package 600 has a surface 408 that extends vertically from the top surface of the package 600 to a bottom surface of the package 600. The surface 408 is orthogonal to the top and bottom surfaces of the package 600 in some examples, and the surface 408 is angled with respect to the top and bottom surfaces of the package 600 in other examples. FIG. 7A is a perspective view of a package 700 having been singulated from a mold compound bar using mold compound trenches that facilitate package singulation, in accordance with various examples. The package 700 of FIG. 7A is identical to package 600 of FIG. 6A, except that the surface 408 extends from the top surface of the package 700 to the bottom surface of the package 700. The trench protrusion 308 used to form the mold compound trench that can produce the surface 408 will have a triangular prism shape. FIG. 7B is a top-down view of the package 700 of FIG. 7A, in accordance with various examples. FIG. 7C is a profile view of the package 700 of FIG. 7A, in accordance with various examples. FIG. 7D is a profile view of the package 700 of FIG. 7A, in accordance with various examples. FIG. 7E is a bottom-up view of the package 700 of FIG. 7A, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die having a device side in which circuitry is formed;
a conductive terminal coupled to the device side of the semiconductor die; and
a mold compound covering the semiconductor die and at least part of the conductive terminal, the conductive terminal exposed to an exterior of the mold compound,
wherein the mold compound has top and bottom surfaces and a lateral side extending between the top and bottom surfaces, the lateral side including:
a first surface contacting the top surface and extending vertically from the top surface toward the bottom surface,
a second surface contacting the first surface and extending horizontally away from the semiconductor die, and
a third surface contacting the second surface and extending from the second surface to contact the bottom surface, the third surface having physical marks resulting from a singulation process, the first and second surfaces lacking physical marks resulting from the singulation process.

2. The package of claim 1, wherein the singulation process is a laser sawing process.

3. The package of claim 1, wherein the singulation process is a mechanical sawing process.

4. The package of claim 1, wherein the first surface is not normal to the second surface.

5. The package of claim 1, wherein a height of the third surface is less than a height of the package.

6. The package of claim 1, further comprising a die pad coupled to the semiconductor die, wherein an edge of the die pad is within 0.5 mm from a closest edge of the bottom surface.

7. The package of claim 1, further comprising a cavity in the lateral side, a floor of the cavity lying in a first horizontal plane that is between a second horizontal plane coincident with the bottom surface and a third horizontal plane coincident with the second surface.

8. The package of claim 7, wherein the cavity is coincident with the top surface, the first surface, the second surface, and the third surface.

9. The package of claim 8, further comprising a die pad coupled to the semiconductor die, wherein a vertical axis extends through an edge of the die pad and through the cavity.

10. A semiconductor package, comprising:
a semiconductor die having a device side in which circuitry is formed;
a conductive terminal coupled to the device side of the semiconductor die; and
a mold compound covering the semiconductor die and at least part of the conductive terminal, the conductive terminal exposed to an exterior of the mold compound,
wherein the mold compound includes a lateral surface extending in a vertical direction and having a height less than a height of the package, the lateral surface having physical marks resulting from a singulation process.

11. The package of claim 10, wherein the mold compound includes a lateral side comprising:
a first surface contacting a top surface of the package and extending vertically toward a bottom surface of the package;
a second surface contacting the first surface and extending horizontally away from the semiconductor die; and
the lateral surface contacting the second surface and extending vertically to contact the bottom surface of the package.

12. The package of claim 11, wherein the first surface is not normal to the second surface.

13. The package of claim 11, further comprising a cavity in the lateral side, the cavity having a floor coincident with a first horizontal plane that lies between a second horizontal plane coincident with the bottom surface and a third horizontal plane coincident with the second surface.

14. The package of claim 13, wherein the cavity is coincident with the top surface, the first surface, the second surface, and the lateral surface.

15. The package of claim 10, wherein the singulation process is a laser sawing process.

16. The package of claim 10, wherein the singulation process is a mechanical sawing process.

17. A method for manufacturing a semiconductor package, comprising:
coupling multiple semiconductor dies to multiple die pads of a high-density lead frame;
coupling each of the multiple semiconductor dies to conductive terminals of the high-density lead frame;
positioning the high-density lead frame and the semiconductor dies in a mold chase, the mold chase having protrusions positioned between consecutive ones of the multiple die pads;
causing mold compound to cover the semiconductor dies in the mold chase and flow underneath the protrusions in the mold chase, wherein portions of the mold compound covering the semiconductor dies are thicker than portions of the mold compound between the semiconductor dies;
removing the high-density lead frame from the mold chase;
trimming the high-density lead frame; and
singulating the mold compound-covered multiple semiconductor dies from each other to produce semiconductor packages, wherein the singulation is performed by using a tool to cut through the portions of the mold compound between the semiconductor dies.

18. The method of claim 17, wherein the protrusions include first bottom surfaces and further include pillars having second bottom surfaces, and wherein the second bottom surfaces extend closer to the lead frame than do the first bottom surfaces.

19. The method of claim 18, wherein the pillars produce cavities that are coincident with multiple surfaces of the semiconductor packages.

20. The method of claim 17, wherein the tool is a laser or mechanical saw.
